(19) United States
(12) Patent Application Publication
(10) Pub. No.: US 2025/0189347 A1
(43) Pub. Date: Jun. 12, 2025

(54) SENSOR DEVICE FOR SEMICONDUCTOR EQUIPMENT, METHOD OF OPERATING A SENSOR DEVICE, AND SYSTEM INCLUDING A SENSOR DEVICE

(71) Applicant: SAMSUNG ELECTRONICS CO., LTD., Suwon-si (KR)

(72) Inventors: Gyoseon Choo, Suwon-si (KR); Juhyun Kim, Suwon-si (KR); Kyeongtea Bang, Suwon-si (KR); Jongmin Song, Suwon-si (KR); Sangrok Oh, Suwon-si (KR); Young Yoon, Suwon-si (KR); Yongwoo Lee, Suwon-si (KR); Juneeok Leem, Suwon-si (KR); Younsok Choi, Suwon-si (KR); Minyoung Hur, Suwon-si (KR)

(21) Appl. No.: 18/798,558

(22) Filed: Aug. 8, 2024

(30) Foreign Application Priority Data
Dec. 7, 2023 (KR) 10-2023-0176879
Jan. 11, 2024 (KR) 10-2024-0004986

(51) Int. Cl. G01D 5/20; G01D 18/00; H01J 37/32; H01L 21/683

(52) U.S. Cl. CPC G01D 5/20; G01D 18/00; H01J 37/32715; H01J 37/32743; H01J 2237/2007; H01J 2237/24564; H01L 21/6831

(57) ABSTRACT

Disclosed is a magnetic field sensor device that measures a magnetic field, the magnetic field sensor device including a sensor unit that senses the magnetic field and generates sensing data, and a processing unit that generates magnetic field data based on the sensing data, wherein the sensor unit includes a sensor substrate, a center sensor positioned on a center of the sensor substrate on the sensor substrate, reference axis sensors arranged on the sensor substrate along a straight line passing through the center of the sensor substrate, and first circumference sensors arranged on the sensor substrate from the center along a circumference having a first radius, and the center sensor, the reference axis sensors, and the first circumference sensors measure magnetic field passing through the center sensor, the reference axis sensors, and the first circumference sensors, respectively.

### CROSS-REFERENCE TO RELATED APPLICATIONS

This application claims priority under 35 U.S.C. § 119 to Korean Patent Application No. 10-2023-0176879 filed on Dec. 7, 2023, and Korean Patent Application No. 10-2024-0004986 filed on Jan. 11, 2024, in the Korean Intellectual Property Office, the disclosures of which are incorporated by reference herein in their entireties.

### BACKGROUND

In manufacturing semiconductor devices, various equipments are used. The semiconductor manufacture equipment may utilize various manners representatively including a manner using a light, a manner using extreme ultraviolet rays, and a manner using plasma. Among them, the semiconductor manufacture equipment using a plasma manner may utilize an electric field or a magnetic field to control the plasma.

The manufacture equipment that uses the magnetic field to control the plasma may efficiently manufacture the semiconductor device by controlling a magnetic field generated by a magnetic coil. Thus, the magnetic field inside the semiconductor manufacture equipment may be measured, the magnetic field may be adjusted based on the measurement result, and thus a process may be modified or designed more efficiently. To this end, a device that measures a magnetic field inside the semiconductor manufacture equipment is required.

### SUMMARY

The present disclosure provides a sensor device that measures a magnetic field inside semiconductor manufacture equipment and a system that may adjust the magnetic field inside semiconductor manufacture equipment or adjust a position in which a wafer or the like is disposed, based on the operation of the sensor device.

According to some implementations, a magnetic field sensor device that measures a magnetic field includes a sensor unit that senses the magnetic field and generates sensing data, and a processing unit that generates magnetic field data based on the sensing data, wherein the sensor unit includes a sensor substrate, a center sensor positioned on a center of the sensor substrate on the sensor substrate, reference axis sensors arranged on the sensor substrate along a straight line passing through the center of the sensor substrate, and first circumference sensors arranged on the sensor substrate from the center along a circumference having a first radius, and the center sensor, the reference axis sensors, and the first circumference sensors measure magnetic field passing through the center sensor, the reference axis sensors, and the first circumference sensors, respectively.

According to some implementations, a method of operating semiconductor manufacture equipment that calibrates a magnetic field includes measuring, by a plurality of sensors, first components, second components, and third components of magnetic field passing through the plurality of sensors and generating magnetic field data including first component measurement values, second component measurement values, and third component measurement values, generating offset magnetic field data by comparing the magnetic field data with reference magnetic field data including first component reference values, second component reference values, and third component reference values, and calibrating the magnetic field based on the offset magnetic field data, wherein the plurality of sensors includes a center senor disposed on a sensor substrate in a center of the sensor substrate, reference axis sensors arranged on the sensor substrate along a straight line passing through the center of the sensor substrate, and first circumference sensors arranged on the sensor substrate from the center of the sensor substrate on a circumference having a first radius.

According to some implementations, a method of operating semiconductor manufacture equipment to calibrate a center of a transfer module includes measuring, by a plurality of sensors, a first component, a second component, and a third component of a magnetic field passing through the plurality of sensors and generating magnetic field data, determining whether a sensor device arranged by the transfer module and including the plurality of sensors is disposed at a center of an electrostatic chuck, based on the magnetic field data, generating center calibration data based on the magnetic field data when the sensor device is not disposed at the center of the electrostatic chuck, and calibrating the center of the transfer module based on the center calibration data, wherein the plurality of sensors include a center senor disposed on a sensor substrate in a center of the sensor substrate, reference axis sensors arranged on the sensor substrate along a straight line passing through the center of the sensor substrate, and first circumference sensors arranged on the sensor substrate from the center of the sensor substrate on a circumference having a first radius.

According to some implementations, a semiconductor manufacture system includes semiconductor manufacture equipment that manufactures a semiconductor device, a system controller that controls the semiconductor manufacture equipment, and a sensor device that measures a magnetic field inside a chamber of the semiconductor manufacture equipment, wherein the semiconductor manufacture equipment includes an electrostatic chuck that positions a wafer thereon, and a transfer module that arranges the wafer on the electrostatic chuck, and the sensor device includes a sensor substrate, a center sensor positioned on a center of the sensor substrate on the sensor substrate, reference axis sensors arranged on the sensor substrate along a straight line passing through the center of the sensor substrate, and first circumference sensors arranged on the sensor substrate from the center along a circumference having a first radius.

### BRIEF DESCRIPTION OF THE DRAWINGS

The above and other features of the present disclosure will become apparent by describing in detail with reference to the accompanying drawings.

FIG. 1 is a block diagram illustrating a semiconductor manufacture system according to some implementations of the present disclosure.

FIG. 2 is a side view illustrating semiconductor manufacturing equipment of FIG. 1 in detail according to some implementations of the present disclosure.

FIG. 3 is a block diagram illustrating a sensor device of FIG. 2 in detail according to some implementations of the present disclosure.

FIG. 4 is a front view illustrating the sensor device of FIG. 2 in detail according to some implementations of the present disclosure.

FIG. 5 is a plan view illustrating a sensor unit FIG. 3 in detail according to some implementations of the present disclosure.

FIG. 6 is a plan view illustrating the sensor unit FIG. 3 in detail according to some implementations of the present disclosure.

FIG. 7 is a view illustrating magnetic field data of the sensor device of FIGS. 3 to 6 according to some implementations of the present disclosure.

FIG. 8 is a view illustrating reference magnetic field data of the semiconductor manufacture equipment according to some implementations of the present disclosure.

FIG. 9 is a view illustrating offset magnetic field data according to some implementations of the present disclosure

FIG. 10 is a flowchart illustrating a sequence for adjusting a magnetic field of the semiconductor manufacture equipment based on the sensor device of FIG. 3 according to some implementations of the present disclosure.

FIG. 11 is a flowchart illustrating a sequence for adjusting a central position of a wafer based on the sensor device of FIG. 3 according to some implementations of the present disclosure.

FIG. 12 is a block diagram illustrating the semiconductor manufacture equipment according to some implementations of the present disclosure.

### DETAILED DESCRIPTION

Hereinafter, implementations of the present disclosure will be described clearly and in detail so that those skilled in the art in the technical field of the present disclosure may easily implement the present disclosure.

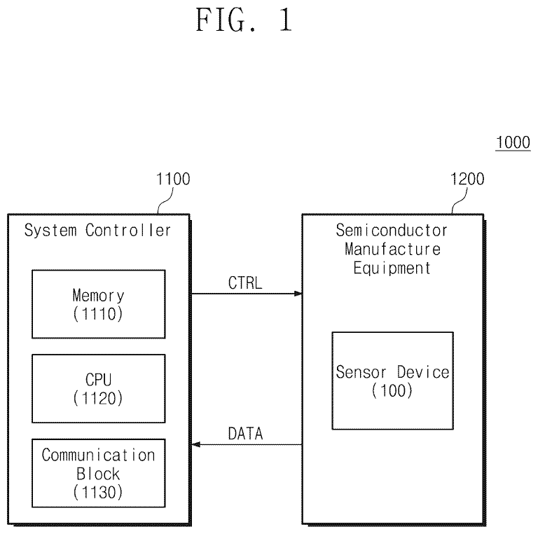

FIG. 1 is a block diagram illustrating a semiconductor manufacture system 1000 according to some implementations of the present disclosure. Referring to FIG. 1, the semiconductor manufacture system 1000 includes a system controller 1100 and semiconductor manufacture equipment 1200. The system controller 1100 includes a memory 1110, a central processing unit (CPU) 1120, and a communication block 1130, and the semiconductor manufacture equipment 1200 includes a sensor device 100. The semiconductor manufacture system 1000 according to some implementations of the present disclosure will be described through FIG. 1.

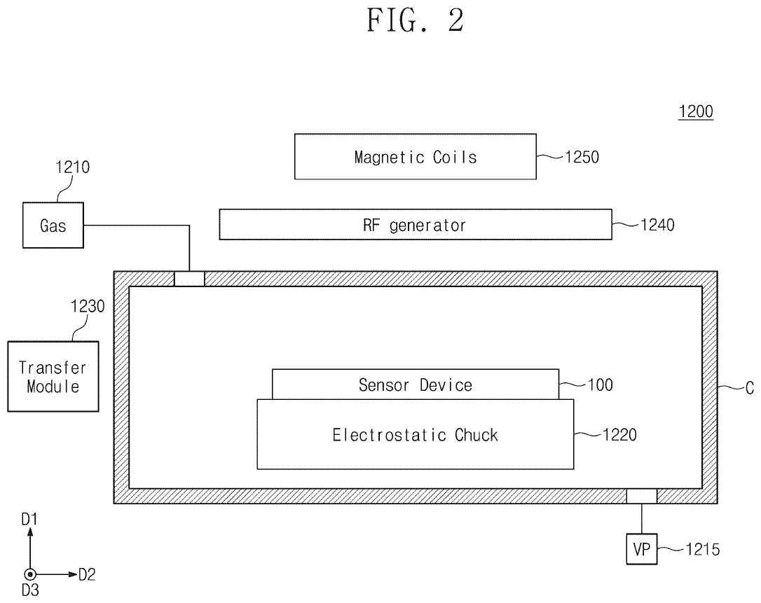

The system controller 1100 may control an operation of the semiconductor manufacture system 1000. In some implementations, the system controller 1100 may control the semiconductor manufacture system 1000 based on controlling of the semiconductor manufacture equipment 1200. For example, the system controller 1100 may control the semiconductor manufacture equipment 1200 based on a control signal CTRL. The system controller 1100 may control various components (e.g., a transmission module in FIG. 2) included in the semiconductor manufacture equipment 1200. FIG. 1 illustrates that the system controller 1100 controls one semiconductor manufacture equipment 1200, but it should be understood that some implementations in which a plurality of semiconductor manufacture equipment are controlled also belong to the scope of the present disclosure.

The memory 1110 may store data required for controlling the semiconductor manufacture equipment 1200. In some implementations, the memory 1110 may include various types of memory elements. For example, the memory 1110 may include a non-volatile memory element (e.g., a flash memory element) or a volatile memory element (e.g., a random access memory (RAM)). The memory 1110 may store various algorithms required for an operation of the semiconductor manufacture equipment 1200 and data associated with the algorithms and may store equipment data DATA received from the semiconductor manufacture equipment 1200.

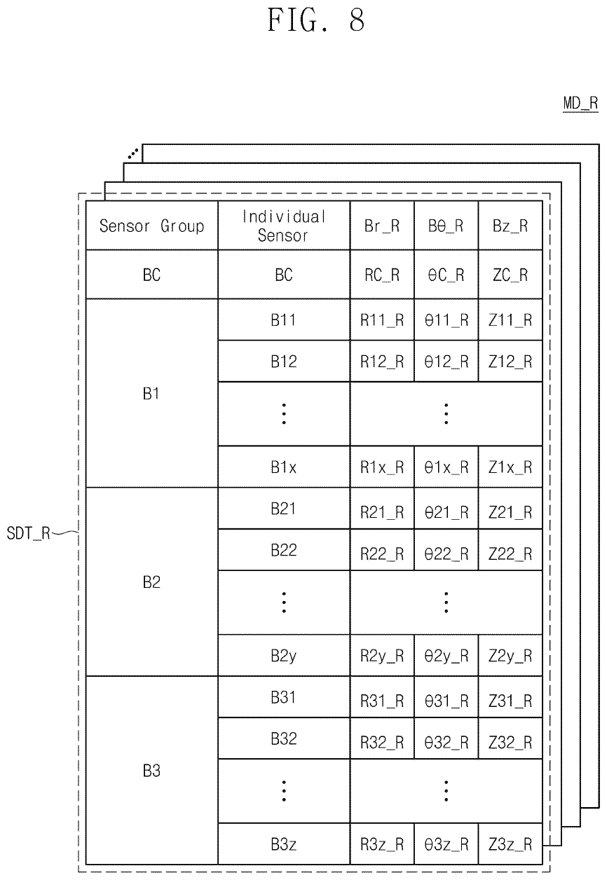

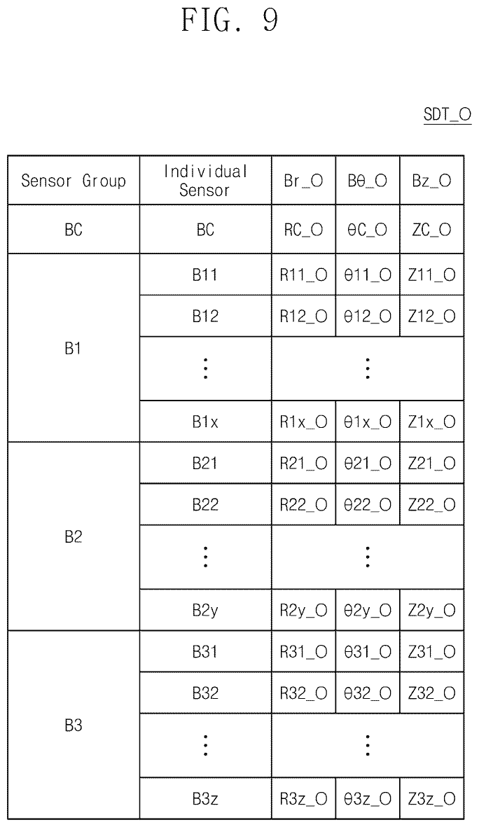

In some implementations, the memory 1110 may store reference magnetic field data. The reference magnetic field data may be data related to a magnetic field required for manufacturing a semiconductor device based on optimal efficiency or an optimal yield rate by the semiconductor manufacture equipment 1200. For example, the memory 1110 may store reference magnetic field data MD_R illustrated and described in FIG. 8. In some implementations, the memory 1110 may store offset magnetic field data. For example, the memory 1110 may store the offset magnetic field data including an offset sensing data table SDT_O of FIG. 9.

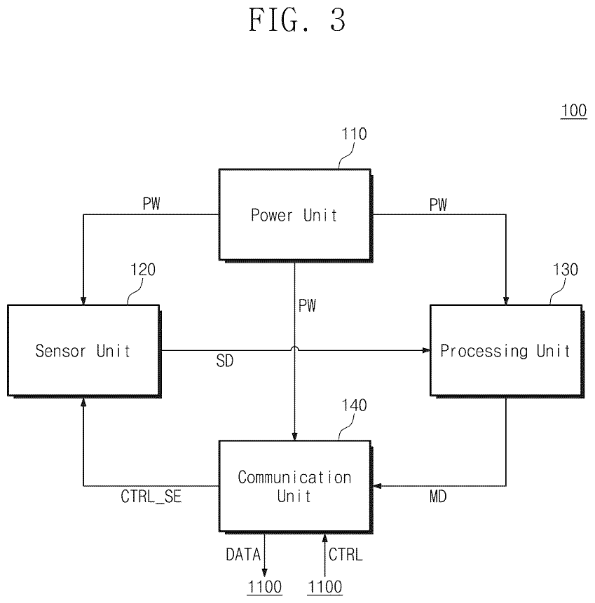

The CPU 1120 may control the system controller 1100. In some implementations, the CPU 1120 may perform various operations and generate control signals. For example, the CPU 1120 may generate the control signal based on the equipment data DATA and the algorithms stored in the memory 1110. In some implementations, the CPU 1120 may include an application-specific integrated circuit (ASIC), a field programmable logic array (FPGA), or an accelerator specialized for a calculation for generating the control signal CTRL. The CPU 1120 may generate the offset magnetic field data based on magnetic field data (e.g., magnetic field data MD of FIG. 3) of the sensor device 100 and the reference magnetic field data. The offset magnetic field data will be described in more detail through FIG. 9.

The communication block 1130 may perform communication between the system controller 1100 and the semiconductor manufacture equipment 1200. In some implementations, the communication block 1130 may allow various signals and data to be transmitted between the system controller 1100 and the semiconductor manufacture equipment 1200. For example, the communication block 1130 may allow the control signal CTRL generated by the CPU 1120 to be transmitted from the system controller 1100 to the semiconductor manufacture equipment 1200 and allow the equipment data DATA to be transmitted from the semiconductor manufacture equipment 1200 to the system controller 1100.

The semiconductor manufacture equipment 1200 may manufacture the semiconductor device. In some implementations, the semiconductor manufacture equipment 1200 may be various equipment or include various equipment. For example, the semiconductor manufacture equipment 1200 may be plasma etching equipment or plasma vapor decomposition equipment or include the plasma etching equipment or the plasma vapor decomposition equipment. The above equipment is only an example, and the scope of the present disclosure should not be limited thereto. The semiconductor manufacture equipment 1200 may transmit the equipment data DATA to the system controller 1100. The semiconductor manufacture equipment 1200 includes the sensor device 100 for measuring various factors used to manufacture the semiconductor device.

The sensor device 100 may measure various factors used in manufacturing the semiconductor device. In some implementations, the sensor device 100 may measure a magnetic field. For example, the sensor device 100 may measure magnetic field used in manufacturing the semiconductor device. In some implementations, the sensor device 100 may transmit the magnetic field measurement results to the system controller 1100 in the form of the equipment data DATA. For example, the sensor device 100 may transmit magnetic field measurement data to the system controller 1100 in the form of the equipment data DATA.

It is illustrated that the sensor device 100 is positioned inside the semiconductor manufacture equipment 1200, but the scope of the present disclosure is not limited thereto. When the sensor device 100 does not measure the magnetic field inside a chamber “C” of the semiconductor manufacture equipment 1200, the sensor device 100 may be positioned outside the semiconductor manufacture equipment 1200. When the semiconductor manufacture equipment 1200 manufactures the semiconductor device, a wafer may be positioned at a position of the sensor device 100, and the sensor device 100 may be positioned outside the semiconductor manufacture equipment 1200. The sensor device 100 will be described in more detail through FIGS. 3 to 7.

FIG. 2 is a side view illustrating structures of the semiconductor manufacture equipment and the sensor device of FIG. 1 according to some implementations of the present disclosure. Referring to FIG. 2, the semiconductor manufacture equipment 1200 includes a gas injector 1210, a gas discharger 1215, an electrostatic chuck (ESC) 1220, a transfer module 1230, a radio frequency (RF) generator 1240, and magnetic coils 1250. The semiconductor manufacture equipment 1200 and the sensor device 100 according to some implementations of the present disclosure will be described through FIG. 2. Hereinafter, for convenience of description, the description will be made based on that the semiconductor manufacture equipment 1200 is plasma equipment, but the scope of the present disclosure should not be limited thereto.

For convenience of description, a first direction D1, a second direction D2, and a third direction D3 are mentioned. A direction perpendicular to the sensor device 100 and toward the RF generator 1240 may be the first direction D1. A direction perpendicular to the first direction D1 and parallel to a horizontal axis of the ESC 1220 may be the second direction D2. A direction perpendicular to the first direction D1 and the second direction D2 may be the third direction D3.

The semiconductor manufacture equipment 1200 may include the chamber “C.” The chamber “C” may be a space in which a vacuum is maintained. For example, the chamber “C” may be a cylindrical space formed based on the first direction D1, the second direction D2, and the third direction D3. In more detail, the chamber “C” may be a cylindrical space having a bottom surface (e.g., a circular surface) on a plane formed in the second direction D2 and the third direction D3 and having a height in the first direction D1. The chamber “C” may provide a vacuum environment required for manufacturing the semiconductor device to the semiconductor manufacture equipment 1200. Although a shape of the chamber “C” is illustrated and described as a cylinder, this is for illustration only, and the scope of the present disclosure is not limited thereto. Further, it should be understood that the chamber “C” having any shape capable of performing the same or similar function belong to the scope of the present disclosure. In some implementations, the chamber “C” includes the ESC 1220 and the sensor device 100 or the wafer therein.

The gas injector 1210 may inject a gas that is a raw material of plasma of the semiconductor manufacture equipment 1200 into the chamber “C.” Referring to FIG. 2, the gas injector 1210 may be positioned at the uppermost end of the chamber “C” in the first direction D1. The gas discharger 1215 may allow the gas injected by the gas injector 1210 to be discharged from the chamber “C.” The gas discharger 1215 may maintain an air pressure of the chamber “C” close to a vacuum based on the gas discharging operation. For example, the gas discharger 1215 may be positioned at the lowermost end of the chamber “C” in the first direction D1. The illustrations and descriptions of the gas injector 1210 and the gas discharger 1215 are examples only, and the scope of the present disclosure is not limited thereto.

The ESC 1220 may enable a semiconductor manufacturing process of the semiconductor manufacture equipment 1200 to be applied to the wafer. In some implementations, the ESC 1220 may position the wafer thereon in the first direction D1 and allow the manufacturing process of the semiconductor manufacture equipment 1200 to be applied to the wafer. The ESC 1220 may be positioned parallel to a plane formed in the second direction D2 and the third direction D3. In some implementations, the ESC 1220 includes the sensor device 100 thereon in the first direction D1.

The transfer module 1230 may position the wafer or the sensor device 100 on the ESC 1220. In some implementations, the transfer module 1230 may include a robot arm and a controller for controlling the robot arm. For example, the transfer module 1230 may allow the sensor device 100 to be positioned on the ESC 1220 in the first direction D1 through the robot arm.

The RF generator 1240 may generate a voltage for generating the plasma. In some implementations, the RF generator 1240 may generate the plasma together with RF oscillators for various frequency ranges. For example, the RF generator 1240 may generate the plasma used in the manufacturing process on the wafer based on a gas (e.g., an argon gas, an oxygen gas, or a xenon gas) flowing inside the semiconductor manufacture equipment 1200 through the gas injector 1210 and the gas discharger 1215. In FIG. 2, the RF generator 1240 is positioned on and parallel to the ESC 1220 and the sensor device 100 in the first direction D1, but the scope of the present disclosure is not limited thereto.

The magnetic coils 1250 may generate the magnetic field required for manufacturing the semiconductor device. The magnetic coils 1250 may control plasma density uniformity inside the chamber “C” (e.g., so that the plasma is uniformly distributed) based on the generation of the magnetic field. In some implementations, the magnetic coils 1250 may generate the magnetic field inside the chamber “C” based on a plurality of currents. For example, by adjusting the plurality of currents flowing inside the magnetic coils 1250, the magnetic field may be generated inside the chamber “C,” and thus the plasma density uniformity may be controlled.

It is illustrated that the magnetic coils 1250 are positioned on the RF generator 1240 in the first direction D1, but the scope of the present disclosure is not limited thereto. It should be understood that some implementations in which the magnetic coils 1250 are positioned on left and right sides from the sensor device 100 in the second direction D2 or some implementations in which magnetic coils positioned from left and right sides from the magnetic coils 1250 and the sensor device 100 in the second direction D2 are included belong to the scope of the present disclosure.

The sensor device 100 may measure magnetic field generated from the magnetic coils 1250. The sensor device 100 may transmit the magnetic field measurement result to the system controller 1100 of FIG. 1. In some implementations, the sensor device 100 may generate the equipment data DATA of FIG. 1 based on the magnetic field measurement. For example, the sensor device 100 may transmit the magnetic field measurement result in the form of the equipment data DATA to the system controller 1100 (e.g., the communication block 1130).

To the extent that the magnetic field generated by the magnetic coils 1250 allows the semiconductor manufacture equipment 1200 to control process distribution over the entire wafer, the measurement of the magnetic field according to a point of the wafer may play an important role in improving process efficiency or yield. The sensor device 100 that may measure the magnetic field inside the semiconductor manufacture equipment 1200 at each point on the wafer will be described with reference to the following drawings. Further, some implementations will be described in which the magnetic field inside the semiconductor manufacture equipment 1200 may be adjusted based on the sensor device 100.

FIG. 3 is a block diagram illustrating the sensor device 100 in detail according to some implementations of the present disclosure. Referring to FIG. 3, the sensor device 100 includes a power unit 110, a sensor unit 120, a processing unit 130, and a communication unit 140. The sensor device 100 according to some implementations of the present disclosure will be described in detail through FIG. 3.

The power unit 110 may provide power to the sensor device 100. In some implementations, the power unit 110 may include a plurality of batteries. For example, the power unit 110 may provide power PW to the sensor unit 120, the processing unit 130, and the communication unit 140 of the sensor device 100 based on power of the plurality of batteries. In some implementations, the power unit 110 may support wireless charging, and the plurality of batteries therein may be charged based on the wireless charging.

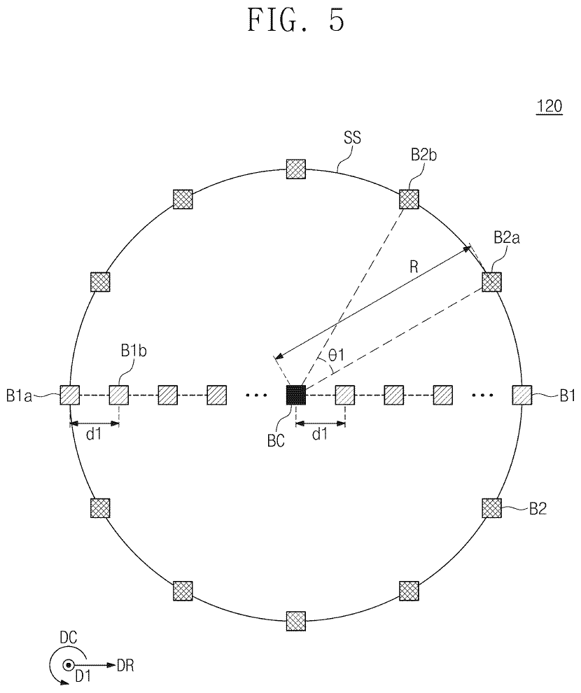

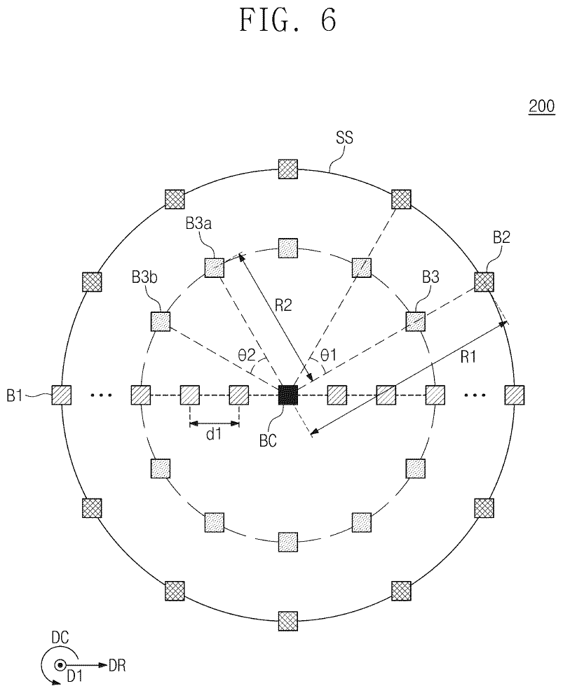

The sensor unit 120 may sense a magnetic field. In some implementations, the sensor unit 120 may include a plurality of sensors. For example, the sensor unit 120 may include Hall sensors that may each measure the magnetic field. The sensor unit 120 may operate in response to a sensor control signal CTRL_SE received from the communication unit 140 and may provide the sensed magnetic field as sensing data SD for each sensor to the processing unit 130. A more detailed structure and operation of the sensor unit 120 will be described through FIGS. 5 and 6.

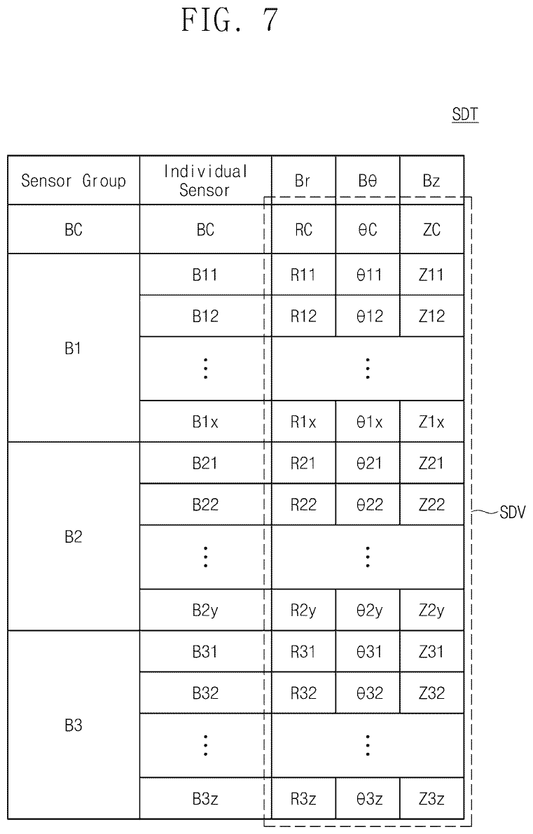

The processing unit 130 may generate the magnetic field data MD included in the equipment data DATA provided to the system controller 1100 of FIG. 1. In some implementations, the magnetic field data MD may be generated based on the sensing data SD. For example, the processing unit 130 may generate the magnetic field data MD for each sensor based on the received sensing data SD for each sensor. The processing unit 130 may transmit the magnetic field data MD to the communication unit 140. The sensing data SD and the magnetic field data MD will be described in more detail through FIG. 7. In some implementations, the processing unit 130 may include a processor (e.g., the CPU, the accelerator, the ASIC, the FPGA or the like) capable of performing the above-described operations.

The communication unit 140 may transmit the equipment data DATA to the system controller 1100 and receive the control signal CTRL from the system controller 1100. In some implementations, the control signal CTRL includes the sensor control signal CTRL_SE that controls the sensor unit 120. For example, the communication unit 140 may transmit the sensor control signal CTRL_SE included in the control signal CTRL to the sensor unit 120. The communication unit 140 may receive the magnetic field data MD from the processing unit 130 and transmit the magnetic field data MD to the system controller 1100 in the form of the equipment data DATA.

The description has been made based on the communication unit 140 generating the sensor control signal CTRL_SE and transmitting the sensor control signal CTRL_SE to the sensor unit 120, but the scope of the present disclosure is not limited thereto. It should be understood that some implementations in which the sensor unit 120 senses the magnetic field and generates the sensing data SD without control of the communication unit 140 also belong to the scope of the present disclosure. For example, the sensor unit 120 may continuously sense the magnetic field and generate the sensing data SD without separate control of the communication unit 140.

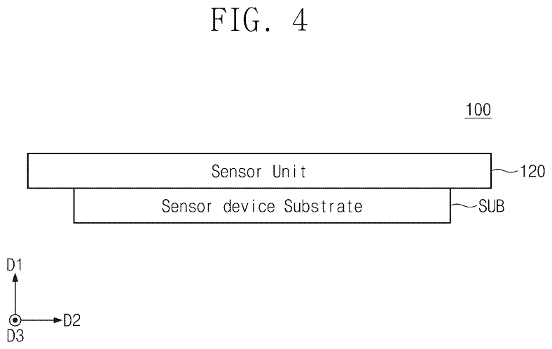

FIG. 4 is a side view illustrating a structure of the sensor device 100 of FIG. 3 according to some implementations of the present disclosure. FIG. 4 may be a side view of the sensor device 100 of FIG. 3 viewed in the third direction D3. Referring to FIG. 4, the sensor device 100 includes a sensor device substrate SUB and the sensor unit 120. The sensor unit 120 may correspond to the sensor unit 120 of FIG. 3 and may sense the magnetic field inside the semiconductor manufacture equipment 1200. In some implementations, the sensor unit 120 may be protected with a case or cover.

The sensor device substrate SUB may be positioned under the sensor unit 120 in the first direction D1. In some implementations, the sensor device substrate SUB may include various units required for an operation of the sensor device 100. For example, the sensor device substrate SUB includes the power unit 110, the processing unit 130, and the communication unit 140 of FIG. 3. FIG. 4 illustrates that the sensor device substrate SUB includes the sensor unit 120 thereon in the first direction D1, but the scope of the present disclosure is not limited thereto, and it should be understood that some implementations in which the sensor unit 120 is positioned under the sensor device substrate SUB in the first direction D1 also belong to the scope of the present disclosure. FIG. 4 illustrates that a width of the sensor device substrate SUB in the second direction D2 is smaller than a width of the sensor unit 120 in the second direction D2, but it should be understood that the widths of the sensor unit 120 and the sensor device substrate SUB in the second direction D2 may be the same.

FIG. 5 is a plan view illustrating the sensor unit 120 of FIG. 3 in detail according to some implementations of the present disclosure. Referring to FIG. 5, the sensor unit 120 includes a sensor substrate SS, a center sensor BC, a first sensor group B1, and a second sensor group B2. The sensor unit according to some implementations of the present disclosure will be explained in detail through FIG. 5.

For convenience of description, implementations of the present disclosure will be described based on a cylindrical coordinate system. For example, the first direction D1 may correspond to the first direction D1 of FIG. 2 and may indicate a center axis of the sensor substrate SS or a normal direction of the sensor substrate SS. A radial direction DR may indicate a distance and direction from the first direction D1 (or the center axis of the sensor substrate SS). A rotational angle DC may be a magnitude of a rotation angle from a reference axis (e.g., a straight line including the first sensor group B1 which will be described below) based on the first direction D1 (or the center axis of the sensor substrate SS) (the magnitude of the rotational angle is stated throughout the specification in terms of 60 degrees). In some implementations, the second direction D2 in FIG. 2 may be the radial direction DR in which the rotational angle DC is 0 degree, and the third direction D3 may be the radial direction DR in which the rotational angle DC is −90 degrees or 270 degrees.

The sensor substrate SS may include a plurality of sensors thereon in the first direction D1. In some implementations, the sensor substrate SS may connect each of the plurality of sensors to the processing unit 130 of FIG. 3. For example, the sensor substrate SS may provide conductive wiring lines that are connected to each of the plurality of sensors and the processing unit 130. The sensor substrate SS may have the same shape as that of the wafer. In some implementations, the sensor substrate SS may have a circular shape and may have the same size as that of the wafer processed by the semiconductor manufacture equipment 1200 of FIG. 2. For example, when a radius of the wafer processed by the semiconductor manufacture equipment 1200 is 150 mm, a radius of the sensor substrate SS may also be 150 mm. In some implementations, the sensor substrate SS may include a notch, which is like the wafer.

The plurality of sensors included in the center sensor BC, the first sensor group B1, and the second sensor group B2 (e.g., the center sensor BC, reference axis sensors of the first sensor group B1, and first circumference sensors of the second sensor group B2) may measure a plurality of components of the magnetic field generated from the magnetic coils 1250 of FIG. 2. In some implementations, the plurality of components may be orthogonal to each other. For example, the plurality of sensors may sense and measure a component of the magnetic field passing through the sensors in the radial direction DR, a component of the magnetic field at the rotational angle DC, and a component of the magnetic field in the first direction D1 based on a cylindrical coordinate system. In more detail, the plurality of sensors may measure the magnetic field passing through the sensors based on the three components of a vector field in the cylindrical coordinate system. As another example, the plurality of sensors may sense or measure the components of the magnetic field passing through the sensors based on one of various coordinate systems such as a Cartesian coordinate system and a spherical coordinate system.

For convenience of description, a description will be made based on some implementations in which the plurality of sensors measures the components of the magnetic field passing through the sensors based on the cylindrical coordinate system. A first component may refer to the component of the magnetic field in the radial direction DR, the second component may refer to the component of the magnetic field at the rotational angle DC, and the third component may refer to the component of the magnetic field in the first direction D1.

The center sensor BC may be positioned at a center of the sensor substrate SS. In FIG. 5, the center sensor BC are illustrated in black shading. In some implementations, the center sensor BC may measure the first to third components of the magnetic field passing through the center of the sensor substrate SS. For example, the third component measured by the center sensor BC may have a negative value other than 0, and the first or second component may be 0.

The first sensor group B1 may include a plurality of reference axis sensors arranged in a row on the sensor substrate SS along a straight line passing through the center sensor BC and parallel to the radial direction DR at which the rotational angle DC is 0 degrees or 180 degrees. In FIG. 5, the reference axis sensors of the first sensor group B1 are illustrated in left diagonal shading. The plurality of reference axis sensors of the first sensor group B1 may measure the first component, the second component, and the third component of the magnetic field passing through the sensors. The first sensor group B1 may sense and measure a change in the first component or a change in the third component in the radial direction DR according to a change in position in the radial direction DR from the center of the sensor substrate SS.

In some implementations, the plurality of reference axis sensors of the first sensor group B1 may be arranged at uniform intervals. For example, a distance between a 1a^{th} sensor B1a and a 1b^{th} sensor B1b may be a first distance d1. The reference axis sensors adjacent to the center sensor BC in the first sensor group B1 may also be spaced apart from each other by the first distance d1 in the radial direction DR. In some implementations, the first distance d1 may be determined based on characteristics of the reference axis sensors of the first sensor group B1. For example, the first distance d1 may be a distance at which a change between the magnetic field of the 1a^{th} sensor B1a and the 1b^{th} sensor B1b (or a change in the first component) may be greater than or equal to magnetic field measurement sensitivity of the reference axis sensors. Likewise, as another example, the first distance d1 may be a distance at which the change between the magnetic field of the reference axis sensors of the first sensor group B1 adjacent to the center sensor BC may be greater than or equal to the magnetic field measurement sensitivity of the sensors.

The arrangement of the reference axis sensors of the first sensor group B1 illustrated and described through FIG. 5 is only an example, and the scope of the present disclosure is not limited thereto. It should be understood that some implementations in which distances between the sensors increase as a distance from the center sensor BC increases or some implementations in which the sensors have arbitrary arrangement distances also belong to the scope of the present disclosure. It should be understood that some implementations in which the first sensor group B1 is parallel to the radial direction DR (i.e., a direction not parallel to the second direction D2 of FIG. 2) at an arbitrary rotational angle DC and is included in or arranged on an axis passing through the center sensor BC also belong to the scope of the present disclosure.

The second sensor group B2 may be disposed on the sensor substrate SS in the first direction D1 along a circumference of a first radius R1 from the center axis. In FIG. 5, the first circumference sensors of the second sensor group B2 may be illustrated in a lattice pattern. In some implementations, the first radius R1 that is a distance between each of the first circumference sensors of the second sensor group B2 and the center sensor BC may be (e.g., approximately) equal to the radius of the wafer. For example, the first circumference sensors of the second sensor group B2 may be arranged on a circumference of the sensor substrate SS and on the sensor substrate SS in the first direction D1. In some implementations, a size of a central angle between adjacent first circumference sensors among the first circumference sensors of the second sensor group B2 may be constant. For example, a size of a central angle between a 2a^{th} sensor B2a and a 2b^{th} sensor B2b of the second sensor group B2 may be a first angle θ1.

The second sensor group B2 may sense and measure changes in the first component, the second component, and the third component according to a change in the rotational angle DC or distribution of values of the first component, the second component, and the third component according to a value of the rotational angle DC. In some implementations, a relationship between center positions of the magnetic coils 1250 and the sensor device 100 of FIG. 2 (e.g., whether the center position of the magnetic coils 1250 and the center position of the sensor device 100 are positioned on the same straight line or are misaligned from each other in the first direction D1) may be identified through the second sensor group B2.

The arrangement of the first circumference sensors of the second sensor group B2 illustrated and described through FIG. 5 is only an example, and the scope of the present disclosure is not limited thereto. It should be understood that some implementations in which sizes of central angles between the sensors of the second sensor group B2 are different according to operation of the magnetic coils 1250 or the semiconductor manufacture equipment 1200 also belong to the scope of the present disclosure. In some implementations, some of the plurality of sensors on the sensor substrate SS may belong to the first sensor group B1 or the second sensor group B2. For example, referring to FIG. 5, the first sensor B1a may be a sensor belonging to both the first sensor group B1 and the second sensor group B2.

Hereinafter, for convenience of description, a description will be made based on a state in which the sensor that may be included in both the first sensor group B1 and the second sensor group B2 is a sensor included in the first sensor group B1, but the present disclosure should be not understood as being limited thereto. The number of sensors illustrated in the first sensor group B1 and the second sensor group B2 is only an example, and it should be understood that some implementations in which the number of sensors included in each group increases or decreases, also belong to the scope of the present disclosure.

The implementations illustrated and described through FIG. 5 have been described based on a state in which a separate sensor substrate SS is included in the sensor unit 120, but the scope of the present disclosure is not limited thereto. It should be understood that some implementations in which the sensor unit 120 of FIG. 5 does not include the sensor substrate SS also belong to the scope of the present disclosure. For example, it should be understood that some implementations in which the center sensor BC, the first sensor group B1, and the second sensor group B2 are included or arranged on the sensor device substrate SUB described in FIG. 4 (e.g., in the first direction D1) also belong to the scope of the present disclosure. As another example, it should be understood that some implementations in which the sensor substrate SS includes the power unit 110, the processing unit 130, and the communication unit 140 of FIG. 3 also belong to the scope of the present disclosure.

The sensing data SD measured through the center sensor BC, the first sensor group B1, and the second sensor group B2 may be provided to the processing unit 130 of FIG. 3. The sensing data SD may include the first component, the second component, and the third component of the magnetic field measured by each sensor. The sensing data SD will be described in more detail through FIG. 7.

FIG. 6 is a plan view illustrating a sensor unit 200 in detail according to some implementations of the present disclosure. The sensor unit 200 may correspond to the sensor unit 120 of FIGS. 3 and 5. Referring to FIG. 6, the sensor unit 200 includes the sensor substrate SS, the center sensor BC, the first sensor group B1, the second sensor group B2, and a third sensor group B3. The center sensor BC, the first sensor group B1, and the second sensor group B2 may be illustrated in the same manner as that in FIG. 5.

The sensor substrate SS may correspond to the sensor substrate SS of FIG. 5 and includes the center sensor BC, the first sensor group B1, the second sensor group B2, and the third sensor group B3 thereon in the first direction D1. The sensor substrate SS may allow the center sensor BC, the first sensor group B1, the second sensor group B2, and the third sensor group B3 to be connected to the processing unit 130 of FIG. 3. The structure and operation of the sensor substrate SS may be the same as or similar to the sensor substrate SS of FIG. 5.

The center sensor BC may correspond to the center sensor BC of FIG. 5, may be positioned at a center of the sensor substrate SS, and may sense and measure the first component, the second component, and the third component of the magnetic field. The first sensor group B1 may correspond to the first sensor group B1 in FIG. 5. Referring to FIG. 6, the reference axis sensors of the first sensor group B1 are parallel to the radial direction DR in which the rotational angle DC is 0 degrees or 180 degrees and are arranged along the straight line passing through the center sensor BC. Like the first sensor group B1 of FIG. 5, the reference axis sensors of the first sensor group B1 may be arranged at the first distance d1, and the reference axis sensors may measure the first component, the second component, and the third component of the magnetic field. It should be understood that some implementations in which the reference axis sensors of the first sensor group B1 are included or arranged on an axis parallel to the radial direction DR of the arbitrary rotational angle DC and passing through the center sensor BC also belong to the scope of the present disclosure.

The second sensor group B2 may correspond to the second sensor group B2 in FIG. 5. Like the second sensor group B2 of FIG. 5, the first circumference sensors of the second sensor group B2 may be arranged on the upper side from the central axis of the second sensor group B2 along a circumference of the first radius R1 in the first direction D1 of the sensor substrate SS. The size of the central angle between adjacent first circumference sensors may be the first angle θ1. The first radius R1 may correspond to the first radius R1 in FIG. 5, and the first angle θ1 may correspond to the first angle 1 in FIG. 5. In some implementations, the first radius R1 may be (e.g., approximately) equal to the radius of the sensor substrate SS (or the wafer). For example, referring to FIG. 6, the first circumference sensors of the second sensor group B2 may be arranged along the circumference of the sensor substrate SS.

Second circumference sensors of the third sensor group B3 may be arranged on the sensor substrate SS in the first direction D1 along a circumference spaced from the center of the sensor substrate SS by a second radius R2. In FIG. 6, the second circumference sensors of the third sensor group B3 are illustrated in gray shading. In some implementations, the second radius R2 may be a different value from that of the first radius R1. For example, the second radius R2 may be smaller than the first radius R1. In some implementations, a size of a central angle between the sensors of the third sensor group B3 may be constant. For example, a size of a central angle between a 3a^{th} sensor B3a and a 3b^{th} sensor B3b of the third sensor group B3 may be a second angle θ2. The second angle θ2 may be the same as the first angle θ1 or may have a different value.

Like the second sensor group B2, the third sensor group B3 may sense and measure the changes in the first component, the second component, and the third component according to a change in the rotational angle DC or the distribution of the values of the first component, the second component, and the third component according to a value of the rotational angle DC. In some implementations, a relationship between center positions of the magnetic coils 1250 and the sensor device 100 of FIG. 2 (e.g., whether center position of the magnetic coils 1250 and center position of the sensor device 100 are positioned on the same straight line or are misaligned from each other in the first direction D1) may be identified through the third sensor group B3. The sensor unit 200 of FIG. 6 additionally includes the third sensor group B3 and thus may identify the relationship between the center positions of the magnetic coils 1250 and the sensor device 100 more precisely than the sensor unit 120 of FIG. 5.

The arrangement and number of the sensors of the first sensor group B1, the second sensor group B2, and the third sensor group B3 illustrated and described through FIG. 6 are examples only, and the scope of the present disclosure is not limited thereto. It should be understood that some implementations in which a distance between the sensors of the first sensor group B1 is not constant or some implementations in which a central angle between the sensors of the second sensor group B2 or the third sensor group B3 is not constant according to the operation of the magnetic coils 1250 or the semiconductor manufacture equipment 1200 also belong to the scope of the present disclosure. It should be understood that some implementations in which the sensor unit 200 further includes a plurality of sensor groups including sensors arranged on a circumference of an arbitrary radius from the central axis also belong to the scope of the present disclosure.

In some implementations, some of the sensors on the sensor substrate SS may belong to the first sensor group B1 and the second sensor group B2 or belong to the first sensor group B1 and the third sensor group B3. For convenience of description, a description is made based on a state in which the sensors that may belong to the first sensor group B1 and the second sensor group B2 or the sensors that may belong to the first sensor group B1 and the third sensor group B3 belong to the first sensor group B1. The number of sensors included in the first sensor group B1, the second sensor group B2, and the third sensor group B3 is only an example, and the present disclosure is not limited to that illustrated in FIG. 6. It should be understood that the number of sensors included in each group may increase or decrease.

The implementations illustrated and described through FIG. 6 have been described based on a state in which a separate sensor substrate SS is included in the sensor unit 200, but the scope of the present disclosure is not limited thereto. It should be understood that some implementations in which the sensor unit 200 of FIG. 6 does not include the sensor substrate SS also belong to the scope of the present disclosure. For example, it should be understood that some implementations in which the center sensor BC, the first sensor group B1, the second sensor group B2, and the third sensor group B3 are included or arranged on the sensor device substrate SUB described in FIG. 4 (e.g., in the first direction D1) also belong to the scope of the present disclosure.

The sensing data SD measured through the center sensor BC, the first sensor group B1, the second sensor group B2, and the third sensor group B3 may be provided to the processing unit 130 of FIG. 3. The sensing data SD may include the first component, the second component, and the third component of the magnetic field measured by each sensor. The sensing data SD will be described in more detail through FIG. 7.

The sensor device 100 illustrated and described through FIGS. 3 to 6 may measure the magnetic field at a plurality of points inside the chamber “C” inside the semiconductor manufacture equipment 1200 of FIG. 2 based on the above-described structure and operation. The sensor device 100 may measure the magnetic field at the plurality of points inside the chamber “C” while maintaining the vacuum environment of the chamber “C,” and the semiconductor manufacture equipment 1200 may apply a process having optimal efficiency and an optimal yield rate to the wafer based on operation, which will be described through the following drawings.

FIG. 7 is a table illustrating a sensing data table SDT of the sensor device 100 of FIGS. 3 to 6 according to some implementations of the present disclosure. The sensing data table SDT may be one example of the magnetic field data MD of FIG. 3 or may be included in the magnetic field data MD. The sensing data table SDT may be generated by the processing unit 130 based on the sensing data SD of the sensor unit 120. The sensing data table SDT according to some implementations of the present disclosure is described through FIGS. 3 and 5 to 7.

The sensing data table SDT may indicate a plurality of rows and a plurality of columns. Each row of the sensing data table SDT may indicate the sensor group, individual sensors included in the sensor group, and measurement values for each component of individual sensor magnetic field. A first column of the sensing data table SDT may indicate the sensor groups BC, B1, B2, and B3 of FIGS. 5 and 6. A second column thereof may represent individual sensors included in the sensor groups BC, B1, B2, and B3. A third column thereof may represent first component measurement values Br (component measurement values of the magnetic field in the radial direction DR) of the magnetic field of the sensors, a fourth column thereof may represent second component measurement values Bθ (component measurement values of the magnetic field at the rotational angle BC) of the magnetic field of the sensors, and a fifth column thereof may represent a third component measurement value Bz (components of the magnetic field in the first direction D1) measured by the sensors. x may indicate the number of reference axis sensors of the first sensor group B1, y may indicate the number of first circumference sensors of the second sensor group B2, and z may indicate the number of second circumference sensors of the third sensor group B3.

A horizontal direction of FIG. 7 sequentially represents the sensor group, the individual sensor included in the sensor group, and the first component measurement value Br, the second component measurement value Bθ, and the third component measurement value Bz of the individual sensor. For example, the first component measurement value Br of the center sensor BC may be RC, the second component measurement value Bθ thereof may be θC, and the third component measurement value Bz thereof may be ZC. As another example, the first component measurement value Br measured by a 22^{th} sensor B22 that is one of the first circumference sensors of the second sensor group B2 may be R22, the second component measurement value Bθ thereof may be θ22, and the third component measurement value Bz may be Z22. Like the above-described example, the sensing data table SDT includes the first component measurement value Br, the second component measurement value Bθ, and the third component measurement value Bz of each of the sensors.

In some implementations, the magnetic field data MD may be data in the form of a matrix. For example, the magnetic field data MD includes measurement values SDV in the form of a matrix and may be transmitted by the processing unit 130 to the communication unit 140. For a more detailed example, a first column of the measurement values SDV includes the first component measurement values Br, a second column thereof includes the second component measurement values Bθ, and a third column includes the third component measurement values Bz.

A description has been made based on some implementations in which the magnetic field data MD is the sensing data table SDT of FIG. 7 or includes the sensing data table SDT, but the scope of the present disclosure is not limited thereto. It should be understood that the magnetic field data MD includes the first component measurement values Br, the second component measurement values B6, and the third component measurement values Bz of the sensors of the sensor groups BC, B1, B2, and B3 in an arbitrary form or an arbitrary structure. In some implementations, the magnetic field data MD includes data illustrated and described through FIG. 7 based on an arbitrary data structure.

The above-described implementations of the magnetic field data MD and the sensing data table SDT has been described based on the sensing data SD of the sensor device 100 including the sensor unit 200 of FIG. 6, but the scope of the present disclosure is not limited thereto. It should be understood that some implementations in which the magnetic field data MD or the sensing data table SDT includes data of the sensor unit 120 of FIG. 5 also belong to the scope of the present disclosure. It should be understood that some implementations in which the magnetic field data MD or the sensing data table SDT includes the first component measurement values Br, the second component measurement values B6, and the third component measurement values Bz of the center sensor BC, the reference axis sensors of the first sensor group B1, and the first circumference sensors of the second sensor group B2 also belong to the scope of the present disclosure (which is the same for the reference magnetic field data MD_R of FIG. 8 and the offset sensing data table SDT_O of FIG. 9, which will be described above).

FIG. 8 is a view illustrating the reference magnetic field data MD_R according to some implementations of the present disclosure. Referring to FIG. 8, the reference magnetic field data MD_R includes a plurality of reference sensing data tables SDT_R. The reference magnetic field data MD_R according to some implementations of the present disclosure is described through FIG. 8.

In some implementations, the reference magnetic field data MD_R includes the reference sensing data table SDT_R for characteristics of, for example, a process of the semiconductor manufacture equipment 1200. For example, the reference magnetic field data MD_R includes the plurality of reference sensing data tables SDT_R that are different from each other according to the process of the semiconductor manufacture equipment, an external environment, a type of wafer, and the like. The reference magnetic field data MD_R may be stored in the system controller 1100 (e.g., the memory 1110).

The reference sensing data table SDT_R may be generated based on characteristics of the semiconductor manufacture system 1000 of FIG. 1. In some implementations, the reference sensing data table SDT_R includes data of the magnetic field measured by the sensors of the sensor device 100 and generated so that the semiconductor manufacture equipment 1200 manufactures the semiconductor device at optimal efficiency and an optimal yield rate. Each reference sensing data table SDT_R may be generated based on methods such as simulation, experiment, or inference through machine learning.

A first column to a fifth column of the reference sensing data table SDT_R may sequentially represent the sensor group, the individual sensors included in the sensor group, and a first component reference value Br_R, a second component reference value Bθ_R, and a third component reference value Bz_R that are measured by the individual sensors.

The first column and the second column of the reference sensing data table SDT_R may be the same as those of the sensing data table SDT of FIG. 7. That is, the individual sensors indicated by rows or corresponding to the rows in the reference sensing data table SDT_R and the sensing data table SDT may be the same. For example, a first row of the reference sensing data table SDT_R and the sensing data table SDT includes the measurement values Br, Bθ, and Bz and the reference values Br_R, Bθ_R, and Bz_R of the center sensor BC, and a third row thereof may indicate the measurement values Br, Bθ, and Bz and the reference values Br_R, Bθ_R, and Bz_R of the 12^{th} sensor B12 of the first sensor group B1.

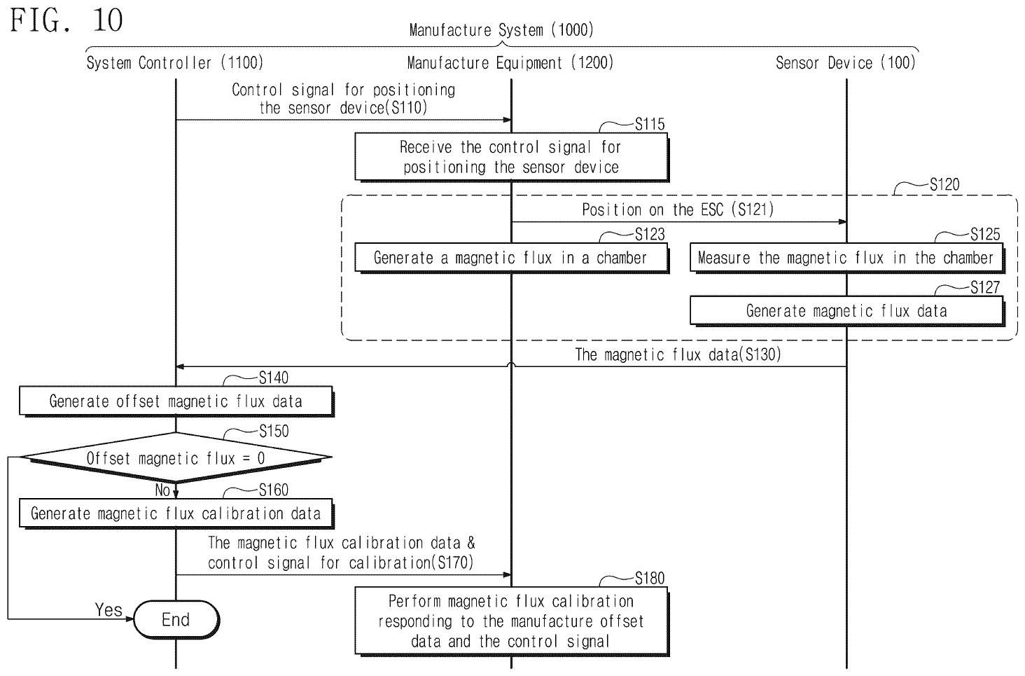

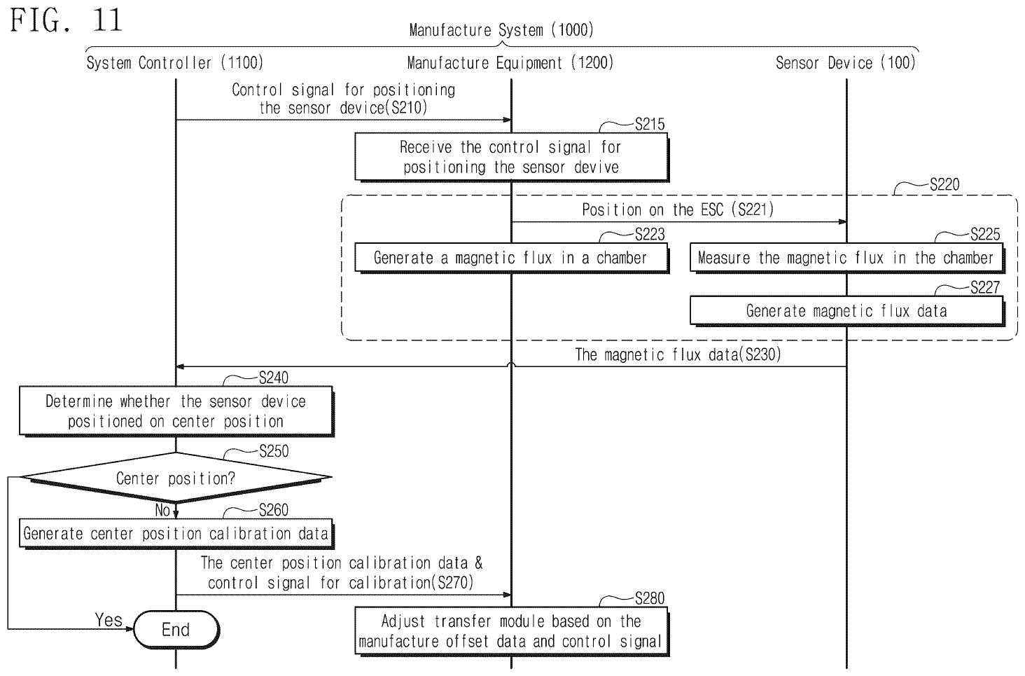

The reference sensing data table SDT_R may be a reference for calibration of the magnetic field and calibration of the center position. More detailed use of the reference sensing data table SDT_R will be described in more detail through FIGS. 10 and 11.

In some implementations illustrated and described through FIG. 8, the reference magnetic field data MD_R includes the plurality of reference sensing data tables SDT_R, but the scope of the present disclosure is not limited thereto. The data described and illustrated by the reference sensing data table SDT_R may be included in the reference magnetic field data MD_R based on an arbitrary arrangement, an arbitrary connection relationship, or an arbitrary structure. For example, the reference data (e.g., the sensor groups BC, B1, B2, and B3), the individual sensors, and the reference values Br_R, Bθ_R, and Bz_R of the individual sensors according to characteristics of the semiconductor process or the like may be included in the reference magnetic field data MD_R in an arbitrary form or an arbitrary structure (e.g., an arbitrary data structure).

FIG. 9 is a table illustrating the offset sensing data table SDT_O according to some implementations of the present disclosure. The offset sensing data table SDT_O may be included in offset magnetic field data of the individual sensors of the sensor groups or may be an example of the offset magnetic field data. The offset sensing data table SDT_O according to some implementations of the present disclosure is described through FIG. 9. In FIG. 9, a description is made based on the fact that the offset magnetic field data has a table form. However, it should be understood that some implementations in which the offset magnetic field data includes data illustrated and described in FIG. 9 based on an arbitrary form or arbitrary structure (e.g., a data structure) also belong to the scope of the present disclosure.

The offset sensing data table SDT_O may be generated based on the sensing data table SDT of FIG. 7 and the reference sensing data table SDT_R of FIG. 8. In some implementations, the offset sensing data table SDT_O may be generated based on differences between the values of the sensing data table SDT and the values of the reference sensing data table SDT_R. For example, a first component offset value Br_O of the center sensor BC may be RC_O, and an equation “(RC_O)=(RC)−(RC_R)” may be satisfied. Likewise, as another example, a second component offset value Rθ_O of the 22^{th} sensor B22 of the second sensor group B2 may be θ22_O, and an equation “(θ22_O)=(θ22)−(θ22_R)” may be satisfied.

The offset sensing data table SDT_O may be generated by the system controller 1100. In some implementations, the offset sensing data table SDT_O may be generated by the CPU 1120 and stored in the memory 1110. For example, the CPU 1120 may generate the offset sensing data table SDT_O based on comparison between the sensing data table SDT (in the form of the magnetic field data MD) included in the equipment data DATA received from the semiconductor manufacture equipment 1200 and the reference sensing data table SDT_R stored in the memory 1110. The generated offset sensing data table SDT_O may be stored in the memory 1110. More detailed use of the offset sensing data table SDT_O is described with reference to FIGS. 10 and 11.

FIG. 7 to 9 illustrate the sensors and the first component data, the second component data, and the third component data of each of the sensors in a table form, but the scope of the present disclosure is not limited thereto. It should be understood that some implementations in which the sensors and data of the sensors as described through FIGS. 7 to 9 are included in an arbitrary data structure also belong to the scope of the present disclosure.

FIG. 10 is a flowchart illustrating a method of operating the semiconductor manufacture system 1000 for magnetic field calibration of the semiconductor manufacture equipment 1200 of FIG. 2 according to some implementations of the present disclosure. A method of calibrating a magnetic field of the semiconductor manufacture equipment 1200 according to some implementations of the present disclosure is described through FIGS. 1 to 10. Throughout the operation of the semiconductor manufacture equipment 1200, the included chamber “C” may maintain an environment (e.g., a vacuum state) required for manufacturing the semiconductor device. Hereinafter, the present disclosure will be described based on the sensor device 100 including the sensor unit 200 of FIG. 6, but it should be understood that some implementations in which the sensor unit 120 of FIG. 5 is included also belong to the scope of the present disclosure (which corresponds to a case in which only the remaining data except for the data corresponding to the third sensor group B3 is present in the tables of FIGS. 7 to 9).

In operation S110, the system controller 1100 may transmit the control signal CTRL for positioning the sensor device 100 on the ESC 1220 to the semiconductor manufacture equipment 1200. For example, the system controller 1100 may generate the control signal CTRL through the CPU 1120 and transmit the generated control signal CTRL to the semiconductor manufacture equipment 1200 through the communication block 1130.

In operation S115, the semiconductor manufacture equipment 1200 may receive the control signal CTRL. In some implementations, the semiconductor manufacture equipment 1200 may transmit the received control signal CTRL to a component that performs an operation indicated by the control signal CTRL. For example, the semiconductor manufacture equipment 1200 may transmit the control signal CTRL that indicates an operation of positioning the sensor device 100 on the ESC 1220 to the transfer module 1230.

Operation S120 may be an operation of measuring, by the sensor device 100, a magnetic field inside the chamber “C” of the semiconductor manufacture equipment 1200. Operation S120 includes operation S121, operation S123, operation S125, and operation S127.

In operation S121, the semiconductor manufacture equipment 1200 may position the sensor device 100 on the ESC 1220. In some implementations, the semiconductor manufacture equipment 1200 may move the sensor device 100 through the transfer module 1230. For example, referring to FIG. 2 together, the semiconductor manufacture equipment 1200 may allow the sensor device 100 to be positioned on an upper side of the ESC 1220 in the first direction D1 based on the operation of the transfer module 1230.

In operation S123, the semiconductor manufacture equipment 1200 may generate a magnetic field inside the chamber “C.” For example, the semiconductor manufacture equipment 1200 may activate the magnetic coils 1250 to generate the magnetic field inside the chamber “C.”

In operation S125, the sensor device 100 may measure the magnetic field inside the chamber “C.” In some implementations, the sensor device 100 may measure the magnetic field inside the chamber “C” based on the sensors included in the sensor unit 120 of FIG. 5. In other implementations, the sensor device 100 includes the sensor unit 200 of FIG. 6 and measure the magnetic field inside the chamber “C” based on the sensors included in the sensor unit 200. The sensors of the sensor device 100 may measure orthogonal components of the magnetic field passing through the sensors inside the chamber “C.” For example, the sensors may measure the magnetic field based on a cylindrical coordinate system and may measure a first component (a component in the radial direction DR), a second component (a component at the rotational angle DC), and a third component (a component in the first direction D1) of the magnetic field. The sensor units 120 and 200 may generate the sensing data SD based on the sensing results by the sensors.

In operation S127, the sensor device 100 may generate the magnetic field data MD. In some implementations, the sensor device 100 may generate the magnetic field data MD based on the sensing data SD generated from the sensor unit 120, and the magnetic field data MD includes the sensing data SD of each of the sensors. For example, the sensor device 100 may generate the magnetic field data MD including the sensing data table SDT of FIG. 7 based on the sensing data SD through the processing unit 130. As another example, the sensor device 100 may generate the magnetic field data MD including the measurement values SDV of the sensing data table SDT of FIG. 7.

In operation S130, the sensor device 100 may transmit the magnetic field data MD to the system controller 1100. In some implementations, the magnetic field data MD may be included in on the equipment data DATA. For example, the equipment data DATA includes the magnetic field data MD of the sensor device 100, and the sensor device 100 may transmit the equipment data DATA including the magnetic field data MD to the communication block 1130.

In operation S140, the system controller 1100 may generate the offset magnetic field data. In some implementations, the system controller 1100 may generate the offset magnetic field data based on the reference magnetic field data MD_R and the magnetic field data MD of FIG. 8. For example, the system controller 1100 may generate the offset magnetic field data based on the reference sensing data table SDT_R of the reference magnetic field data MD_R and the magnetic field data MD or the sensing data table SDT included in the magnetic field data MD. In some implementations, the offset magnetic field data may be the offset sensing data table SDT_O of FIG. 9.

The system controller 1100 may generate the offset magnetic field data based on differences between the corresponding data (e.g., a measurement value for each component or a reference value for each component) included in the magnetic field data MD and the reference magnetic field data MD_R. In some implementations, the system controller 1100 may generate the offset sensing data table SDT_O based on differences between corresponding values of the sensing data table SDT and the reference sensing data table SDT_R. For example, referring to FIGS. 7 to 9 together, R2y_O that is the first component offset value Br_O of a 2y^{th} sensor B2y of the offset sensing data table SDT_O may be a value obtained by subtracting R2y_R that is the first component reference value Br_R of a 2y^{th} sensor B2y of the reference sensing data table SDT_R from R2y that is the first component measurement value Br of a 2y^{th} sensor B2y of the sensing data table SDT. As another example, Z12_O that is a third component offset value Bz_O of the 12^{th} sensor B12 of the offset sensing data table SDT_O may be a value obtained by subtracting Z12_R that is the third component reference value Bz_R of the 12^{th} sensor B12 of the reference sensing data table SDT_R from Z12 that is the third component measurement value Bz of the 12^{th} sensor B12 of the sensing data table SDT.

In operation S150, the system controller 1100 may determine whether a magnitude of the offset magnetic field is 0. In some implementations, the system controller 1100 may determine that the magnitude of the offset magnetic field is 0 when the values of all the components of the offset sensing data table SDT_O are 0. When the magnitude of the offset magnetic field is 0, the system controller 1100 may terminate calibration of the magnetic field of the semiconductor manufacture equipment 1200. When the magnitude of the offset magnetic field is not 0, the system controller 1100 may proceed to operation S160.

In operation S160, the system controller 1100 may generate magnetic field calibration data. In some implementations, the system controller 1100 may generate the magnetic field calibration data based on the offset sensing data table SDT_O and a magnetic field calibration algorithm. For example, the system controller 1100 may generate the magnetic field calibration data by applying the offset sensing data table SDT_O to the magnetic field calibration algorithm stored in the memory 1110. The magnetic field calibration data may be data for controlling the magnetic coils 1250. For example, the magnetic field calibration data may be data including values of a plurality of currents required by generating the magnetic field of the magnetic coils 1250 or a pattern of the values of the plurality of currents.

In operation S170, the system controller 1100 may transmit the magnetic field calibration data and the control signal CTRL for calibration to the semiconductor manufacture equipment 1200. For example, the system controller 1100 may transmit the magnetic field calibration data and the control signal CTRL for calibration to the semiconductor manufacture equipment 1200 through the communication block 1130.

In operation S180, the semiconductor manufacture equipment 1200 may perform the magnetic field calibration in response to the control signal CTRL for calibration and the magnetic field calibration data. For example, the semiconductor manufacture equipment 1200 may adjust the plurality of currents flowing inside the magnetic coils 1250 according to the magnetic field calibration data and change the magnetic field generated by the magnetic coils 1250 such that the magnetic field matches the magnetic field calibration data. When the magnetic field calibration is successfully performed, the values of the components of the sensors of the magnetic field data MD measured by the sensor device 100 may be the same as corresponding values of the reference sensing data table SDT_R.

After operation S180, the semiconductor manufacture system 1000 returns back to operation S120 and may measure the magnetic field inside the chamber “C.” For example, when the sensor device 100 is positioned on the ESC 1220, the semiconductor manufacture equipment 1200 may return to operation S123 after operation 180 is terminated and may sequentially perform the above-described operations from operation S123. As another example, when the semiconductor manufacture equipment 1200 continuously generates the magnetic field, the semiconductor manufacture system 1000 may return back to operation S125, and the sensor device 100 may sense the magnetic field generated based on the magnetic field calibration data. Thereafter, the semiconductor manufacture system 1000 may sequentially perform the above-described operations.

The semiconductor manufacture system 1000 may generate a magnetic field for optimal processing based on the operating method illustrated and described through FIG. 10. The sensor device 100 of FIG. 3 may measure the magnetic field while the chamber “C” does not deviate from the vacuum state. This may reduce costs consumed in the process of the semiconductor manufacture system 1000 or may reduce a time consumed in magnetic field measurement and calibration. Further, the sensor device 100 may provide more precise measurement of the magnetic field at a plurality of points inside the chamber “C” based on the magnetic field measurement at the points. The semiconductor manufacture system 1000 may more precisely control the magnetic field inside the chamber “C” based on such measurement data, and the magnetic field may reach a set value of the magnetic field for optimal processing (e.g., magnitudes of the currents flowing inside the magnetic coils 1250) in a shorter time and more easily.

FIG. 11 is a flowchart illustrating a method of operating a semiconductor manufacture system for calibrating a center of the wafer of the semiconductor manufacture equipment 1200 according to some implementations of the present disclosure. The method of operating the semiconductor manufacture system for wafer center position calibration using the magnetic field of the semiconductor manufacture equipment 1200 according to some implementations of the present disclosure is described through FIGS. 1 to 7 and 11. In some implementations, the sensor device 100 may have the same size and notch as those of the wafer. Thus, the wafer center position calibration may be performed based on adjusting the operation of the transfer module 1230 based on whether the sensor device 100 is disposed on a center.

In operation S210, the system controller 1100 may transmit the control signal CTRL for positioning the sensor device 100 on the ESC 1220 to the semiconductor manufacture equipment 1200. Operation S210 may correspond to operation S110 of FIG. 10, and the semiconductor manufacture system 1000 may operate the same as or similar to operation S110.

In operation S215, the semiconductor manufacture equipment 1200 may receive the control signal CTRL. In operation S215, the semiconductor manufacture equipment 1200 may operate the same as or similar to operation S115 of FIG. 10. For example, the semiconductor manufacture equipment 1200 may transmit the control signal CTRL to a component (e.g., the transfer module 1230) that performs an operation indicated by the control signal CTRL.

Operation S220 may be an operation of measuring, by the sensor device 100, the magnetic field inside the chamber “C” of the semiconductor manufacture equipment 1200. Operation S220 may correspond to operation S110 of FIG. 10. Operation S220 includes operation S221, operation S223, operation S225, and operation S227, which correspond to operation S121, operation S123, operation S125, and operation S127, respectively. Operation S221, operation S223, operation S225, and operation S227 of the semiconductor manufacture system 1000 may be the same as or similar to operation S121, operation S123, operation S125, and operation S127, respectively.

In operation S221, the semiconductor manufacture equipment 1200 may position the sensor device 100 on the ESC 1220, and in operation S223, the semiconductor manufacture equipment 1200 may generate the magnetic field inside the chamber “C.” In operation S225, the sensor device 100 may measure the magnetic field inside the chamber “C,” and in operation S227, the sensor device 100 may generate the magnetic field data MD based on the measurement.

In operation S230, the sensor device 100 may transmit the generated magnetic field data MD to the system controller 1100. Operation S230 may correspond to operation S130 of FIG. 10. For example, the sensor device 100 may transmit the equipment data DATA including the magnetic field data MD to the system controller 1100,

In operation S240, the system controller 1100 may determine whether the sensor device 100 is positioned at a center position of the ESC 1220. The system controller 1100 may determine whether the sensor device 100 is disposed at the center position based on the sensing data table SDT of FIG. 7 included in the magnetic field data MD.

In some implementations, the system controller 1100 may determine whether the sensor device 100 is positioned at the center position based on the measurement values of the center sensor BC. For example, referring to FIG. 8 together, the system controller 1100 may determine that the sensor device 100 is not disposed at the center position when BC that is the first component measurement value Br of the center sensor BC of the sensing data table SDT included in the magnetic field data MD or 6C that is the second component measurement value Bθ thereof is not 0. This is because, when the magnetic field is generated above the center position of the sensor device 100 in an opposite direction to the first direction D1, the first components (magnetic field components in the radial direction DR) are all symmetric and are canceled out.

In other implementations, the system controller 1100 may determine whether the sensor device 100 is positioned at the center position based on the measurement values of the arbitrary components of the sensors. For example, the system controller 1100 may determine that the sensor device 100 is not positioned at the center position when at least one of the second component measurement values Bθ of the sensors included in the sensor device 100 is not 0. This is because, when the magnetic field is generated above the center position of the sensor device 100 in the first direction D1 and is radiated in an opposite direction to the first direction D1 and the radial direction DR, the values of the second component (i.e., a component of the magnetic field at the rotational angle DC) measured by the sensors are 0.

The above-described implementations are only examples, and the scope of the present disclosure is not limited thereto. The standards for reference components and measurement values of the components among the measurement value of the magnetic components may be different from each other according to the positions of the magnetic coils 1250, coordinate components (e.g., the Cartesian coordinate system or the spherical coordinate system) of a coordinate system having orthogonal components that measure the magnetic field, the number of sensors that are standards for determining the center position, and the like. In other implementations, the reference magnetic field data MD_R includes reference magnetic field data MD_R including reference values for the components of the sensors when the sensor device 100 is located at the center position, and whether the sensor device 100 is positioned at the center position may be determined based on comparison with the magnetic field data MD.

In operation S250, the system controller 1100 may determine whether to proceed to a next operation based on the determination result of operation S240. When it is determined in operation S240 that the sensor device 100 is positioned as the center position, the system controller 1100 may terminate a wafer center position calibration operation of the semiconductor manufacture system 1000. When it is determined in operation S240 that the sensor device 100 is not positioned at the center position, the system controller 1100 may allow the semiconductor manufacture system 1000 to proceed to operation S260.

In operation S260, the system controller 1100 may generate center position calibration data based on the sensing data table SDT. The center position calibration data may be data for adjusting an operation of the transfer module 1230. In some implementations, the system controller 1100 may generate the center position calibration data based on the data of the sensing data table SDT and a center position calibration algorithm.

For example, when the system controller 1100 determines the center position based on the measurement values of the magnetic field components of the center sensor BC of the sensing data table SDT, the system controller 1100 may generate the center position calibration data based on the first component measurement value Br or the second component measurement value B6 and the algorithm. As another example, when the system controller 1100 determines the center position based on the second component measurement values Bθ of the sensors of the sensing data table SDT, the system controller 1100 may generate the center position calibration data based on the second component measurement values Bθ of the sensors and the algorithm. Likewise, when the system controller 1100 determines the center position in a manner other than the above-described example manners, the system controller 1100 may generate the center position calibration algorithm based on an algorithm and measurement values corresponding to the corresponding manner.

In operation S270, the system controller 1100 may transmit the center position calibration data and the control signal CTRL that indicates the center position calibration to the semiconductor manufacture equipment 1200. Like operation S170 of FIG. 10, the system controller 1100 may transmit the center position calibration data and the control signal CTRL for the center position calibration to the semiconductor manufacture equipment 1200 through the communication block 1130.

In operation S280, the semiconductor manufacture equipment 1200 may perform the center position calibration in response to the center position calibration data and the control signal CTRL for the center position calibration. For example, the semiconductor manufacture equipment 1200 may control or adjust the operation of the transfer module 1230 according to the center position calibration data and calibrate the center position of the sensor device 100 (or the wafer) based thereon. For example, when the center position calibration is successfully performed, the first component measurement value Br and the second component measurement value Bθ of the center sensor BC, which is measured by the sensor device 100, are 0 or the second component measurement values Bθ of the sensors may all be 0.

After operation S280, the semiconductor manufacture system 1000 returns back to operation S220 and may measure the magnetic field inside the chamber “C.” In some implementations, the semiconductor manufacture equipment 1200 may perform operation S280 and then return to operation S220 to measure the magnetic field. For example, when the sensor device 100 is positioned on the ESC 1220, the semiconductor manufacture equipment 1200 may return to operation S223 after operation 280 is terminated and may sequentially perform the above-described operations from operation S223. As another example, when the semiconductor manufacture equipment 1200 continuously generates the magnetic field, the semiconductor manufacture system 1000 may return back to operation S225, and the sensor device 100 may sense the magnetic field generated based on the magnetic field calibration data. Thereafter, the semiconductor manufacture system 1000 may sequentially perform the above-described operations.

The wafer may be easily disposed at the center position of the ESC 1220 by the transfer module 1230 based on the wafer center position calibration operation illustrated and described through FIG. 11. In particular, the operation of the sensor device 100 described through FIGS. 1 to 9 and FIG. 11 may control the transfer module 1230 to operate the transfer module 1230 for arranging the wafer on a center of the ESC 1220 without changing an environment for manufacturing the semiconductor device, which is like the vacuum environment of the chamber “C” of the semiconductor manufacture equipment 1200. This may provide cost savings for generating the vacuum environment according to an environmental change in the chamber “C” and rapid adjustment of the transfer module 1230.

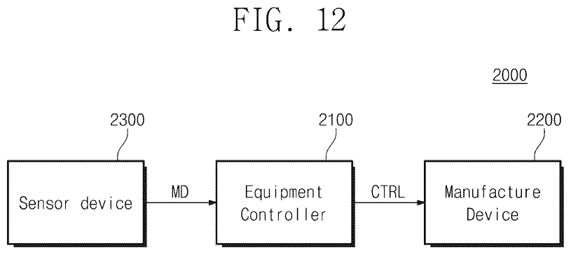

FIG. 12 is a block diagram illustrating the semiconductor manufacture equipment according to some implementations of the present disclosure. Referring to FIG. 12, semiconductor manufacture equipment 2000 includes an equipment controller 2100, a manufacture device 2200, and a sensor device 2300. The semiconductor manufacture equipment 2000 according to some implementations of the present disclosure is described through FIG. 12.

The equipment controller 2100 may control the overall operation of the semiconductor manufacture equipment 2000. In some implementations, the equipment controller 2100 may control the manufacture device 2200 based on the control signal CTRL and receive the magnetic field data MD from the sensor device 2300. The equipment controller 2100 may operate the same as or similar to the system controller 1100 described through FIGS. 1 to 11 and control the manufacture device 2200 or receive the data from the sensor device 2300.

The manufacture device 2200 may manufacture the semiconductor device. In some implementations, the manufacture device 2200 may manufacture the semiconductor device in response to the control signal CTRL of the equipment controller 2100. The manufacture device 2200 may operate the same as or similar to the semiconductor manufacture equipment 1200 described through FIGS. 1 to 11.

The sensor device 2300 may measure the magnetic field inside the chamber included in the manufacture device 2200. In some implementations, the sensor device 2300 may transmit the measured magnetic field data MD to the equipment controller 2100. The sensor device 2300 may correspond to the sensor device 100 described through FIGS. 1 to 11 and may operate the same as or similar to the sensor device 100.

The semiconductor manufacture equipment 2000 of FIG. 12 may measure the magnetic field inside the chamber without changing the vacuum environment of the chamber included in the manufacture device 2200 based on the sensor device 2300 and may reduce costs of moving the chamber between an atmosphere environment and the vacuum environment. Further, the sensor device 2300 is handled inside the manufacture device 2200 in the same manner as that of the wafer and thus may easily measure the magnetic field inside the chamber. The semiconductor manufacture equipment 2000 may more easily calibrate the magnetic field inside the chamber or easily perform the center position calibration of the wafer based on the magnetic field data generated by the sensor device 2300.

According to some implementations of the present disclosure, a sensor device that measures a magnetic field inside semiconductor manufacture equipment and a system that may adjust the magnetic field inside semiconductor manufacture equipment or adjust a position in which a wafer or the like is disposed, based on the operation of the sensor device are provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The above descriptions are specific implementations for implementing the present disclosure. The present disclosure may also include implementations that may be simply changed or easily changed in design as well as the above-described implementations. Further, the present disclosure may include technologies that may be easily modified and implemented using some implementations. Thus, the scope of the present disclosure should not be limited to the above-described implementations and should be determined by equivalents to the appended claims of the present disclosure as well as the appended claims.

1. A magnetic field sensor device configured to measure a magnetic field, the magnetic field sensor device comprising:
a sensor unit configured to sense the magnetic field and generate sensing data; and
a processor configured to generate magnetic field data based on the sensing data,
wherein the sensor unit includes:
a sensor substrate;
a center sensor positioned on a center of the sensor substrate;
a plurality of reference axis sensors arranged on the sensor substrate along a straight line passing through the center of the sensor substrate; and
a plurality of first circumference sensors on the sensor substrate, the plurality of first circumference sensors being arranged from the center along a circumference having a first radius, and
wherein the center sensor, the plurality of reference axis sensors, and the plurality of first circumference sensors are configured to measure magnetic field passing through the center sensor, the reference axis sensors, and the first circumference sensors, respectively.

2. The magnetic field sensor device of claim 1, wherein the plurality of reference axis sensors are spaced apart from one another by a first distance at which a change in a magnetic field between adjacent reference axis sensors is greater than magnetic field measurement sensitivity of the reference axis sensors.

3. The magnetic field sensor device of claim 1, wherein the first radius is the same as a radius of the sensor substrate.

4. The magnetic field sensor device of claim 3, wherein central angles between adjacent first circumference sensors among the plurality of first circumference sensors are the same.

5. The magnetic field sensor device of claim 3, wherein
the center sensor is configured to measure a first component, a second component, and a third component of the magnetic field passing through the center sensor,
the plurality of reference axis sensors are configured to measure a first component, a second component, and a third component of the magnetic field passing through the plurality of reference axis sensors,
the plurality of first circumference sensors are configured to measure a first component, a second component, and a third component of the magnetic field passing through the plurality of first circumference sensors, and
wherein the first component, the second component, and the third component of each of the center sensor, the plurality of reference axis sensors, the plurality of first circumference sensors are orthogonal to each other.

6. The magnetic field sensor device of claim 5, wherein the sensor unit further includes a plurality of second circumference sensors, and
wherein the plurality of second circumference sensors are positioned on the sensor substrate and arranged from the center along a circumference having a second radius.

7. The magnetic field sensor device of claim 6, wherein the processor is configured to generate magnetic field data, and wherein the magnetic field data includes:
measurement values of the first component respectively sensed by the center sensor, the plurality of reference axis sensors, and the plurality of first circumference sensors, and a measurement value of a first component sensed by the plurality of second circumference sensors;
measurement values of the second component respectively sensed by the center sensor, the plurality of reference axis sensors, and the plurality of first circumference sensors, and a measurement value of a second component sensed by the plurality of second circumference sensors; and
measurement values of the third component respectively sensed by the center sensor, the plurality of reference axis sensors, and the plurality of first circumference sensors, and a measurement value of a third component sensed by the plurality of second circumference sensors.

8. The magnetic field sensor device of claim 6, wherein the plurality of second circumference sensors are configured to measure the first component, the second component, and the third component of the magnetic field passing through the plurality of second circumference sensors.

9. The magnetic field sensor device of claim 7,
wherein the center sensor, the plurality of reference axis sensors, the plurality of first circumference sensors, and the plurality of second circumference sensors each are configured to measure the first component, the second component, and the third component based on a cylindrical coordinate system,
wherein the first component is a radial component that is positioned on the substrate in a direction away from the center of the sensor substrate, and wherein the first component is perpendicular to a circumference of the sensor substrate,
wherein the second component is a rotational angle component, wherein the rotational angle component uses as a reference axis a straight line connecting the plurality of reference axis sensors on the sensor substrate, and
wherein the third component is a central axial component of the sensor substrate.

10. The magnetic field sensor device of claim 7,
wherein the magnetic field data includes a sensing data table, and
wherein the sensing data table includes the measurement values of the first component, the measurement values of the second component, and the measurement values of the third component sensed by each of the center sensor, the plurality of reference axis sensors, the plurality of first circumference sensors, and the plurality of second circumference sensors.

11. A semiconductor manufacture equipment, comprising:
a sensor device including a plurality of sensors;
an electrostatic chuck configured to position the sensor device thereon; and
a chamber configured to include the sensor device, and the electrostatic chuck,
wherein the plurality of sensors measures a plurality of first components of magnetic field, a plurality of second components of the magnetic field, and a plurality of third components of the magnetic field,
wherein the magnetic field passes through the plurality of sensors,
wherein the sensor device obtains magnetic field data including a plurality of first component measurement values, a plurality of second component measurement values, and a plurality of third component measurement values, and generates offset magnetic field data by comparing the magnetic field data with reference magnetic field data including a plurality of first component reference values, a plurality of second component reference values, and a plurality of third component reference values,
wherein the plurality of sensors include:
a center senor disposed on a sensor substrate at a center of the sensor substrate;
a plurality of reference axis sensors arranged on the sensor substrate along a straight line passing through the center of the sensor substrate; and
a plurality of first circumference sensors on the sensor substrate and arranged from the center of the sensor substrate on a circumference having a first radius, and
wherein the semiconductor manufacture equipment calibrates the magnetic field based on the offset magnetic field data.

12. The semiconductor manufacture equipment of claim 11, wherein the plurality of sensors further include:
a plurality of second circumference sensors on the sensor substrate, the plurality of second circumference sensors being arranged from the center of the sensor substrate on a circumference having a second radius, and
wherein the second radius is smaller than the first radius.

13. The semiconductor manufacture equipment of claim 12, wherein the offset magnetic field data includes a plurality of first differences between the a plurality of first component measurement values and the a plurality of first component reference values, a plurality of second differences between the a plurality of second component measurement values and the a plurality of second component reference values, and a plurality of third differences between the a plurality of third component measurement values and the a plurality of third component reference values.

14. The semiconductor manufacture equipment of claim 12, wherein the sensor device calibrates the magnetic field by generating the magnetic field inside the chamber using a plurality of magnetic coils, wherein a plurality of currents flow through the plurality of magnetic coils, and changes the plurality of currents inside the magnetic coils based on magnetic field calibration data generated based on the offset magnetic field data.

15. The semiconductor manufacture equipment of claim 12, wherein the first component is a radial component disposed on the sensor substrate away from the center of the sensor substrate in a direction perpendicular to the circumference of the sensor substrate,
wherein the second component is a rotational angle component which is disposed on the sensor substrate,
wherein the rotational angle component uses the straight line as a reference axis, and
wherein the third component is a component in a central axial direction of the sensor substrate.

16. The semiconductor manufacture equipment of claim 12, wherein the plurality of reference axis sensors are spaced apart from one another by a first distance at which a change in a magnetic field between adjacent reference axis sensors is greater than magnetic field measurement sensitivity of the reference axis sensors.

17. The semiconductor manufacture equipment of claim 13, wherein the sensor device terminates a magnetic field calibration operation of the semiconductor manufacture equipment, when all the plurality of first differences, the plurality of second differences, and the plurality of third differences are 0.

18. A semiconductor manufacture equipment, comprising:
a sensor device including a plurality of sensors;
an electrostatic chuck configured to position the sensor device thereon;
a transfer module configured to position a wafer on the electrostatic chuck; and
a chamber configured to include the sensor device and the electrostatic chuck,
wherein the plurality of sensors measures a plurality of first components of magnetic field, a plurality of second components of the magnetic field, and a plurality of third components of the magnetic field,
wherein the magnetic field passes through the plurality of sensors,
wherein the sensor device obtains magnetic field data, determines whether the sensor device arranged by the transfer module is disposed at a center of the electrostatic chuck, based on the magnetic field data, and generates center calibration data based on the magnetic field data when the sensor device is not disposed at the center of the electrostatic chuck,
wherein the plurality of sensors include:
a center senor on a sensor substrate, the center sensor being arranged in a center of the sensor substrate;
a plurality of reference axis sensors on the sensor substrate, the plurality of reference axis sensors being arranged along a straight line passing through the center of the sensor substrate; and
a plurality of first circumference sensors on the sensor substrate, the plurality of first circumference sensors being arranged from the center of the sensor substrate on a circumference having a first radius, and
wherein the semiconductor manufacture equipment calibrates the transfer module to position the wafer on the center of the electrostatic chuck, based on the center calibration data.

19. The semiconductor manufacture equipment of claim 18,
wherein the first component is a radial component disposed on the sensor substrate away from the center of the sensor substrate in a direction perpendicular to the circumference of the sensor substrate,
wherein the second component is a rotational angle component which is disposed on the sensor substrate,
wherein the rotational angle component uses the straight line as a reference axis, and
wherein the third component is a component in a central axial direction of the sensor substrate.

20. The semiconductor manufacture equipment of claim 19,
wherein whether the sensor device is positioned at the center of the electrostatic chuck is determined based on the second component, and
wherein, when second component measurement values measured by all of the plurality of sensors are 0, it is determined that the sensor device is positioned at the center of the electrostatic chuck.

21.-28. (canceled)
